(19) United States
(12) Patent Application Publication
(10) Pub. No.: US 2025/0198804 A1
(43) Pub. Date: Jun. 19, 2025

(54) METHOD FOR DETECTING A PRESENCE OF A HUMAN HAND IN A GRIPPING AREA OF A STEERING WHEEL

(71) Applicant: KOSTAL Automobil Elektrik GmbH & Co. KG, Luedenscheid (DE)

(72) Inventors: Christian BRÜGGEMANN, Waltrop (DE); Matthias SEIFERT, Bochum (DE); Tobias HEINLOTH, Dortmund (DE)

(73) Assignee: KOSTAL Automobil Elektrik GmbH & Co. KG, Luedenscheid (DE)

(21) Appl. No.: 19/067,749

(22) Filed: Feb. 28, 2025

Related U.S. Application Data
(63) Continuation of application No. PCT/EP2023/076497, filed on Sep. 26, 2023.

(30) Foreign Application Priority Data
Sep. 29, 2022 (DE) 102022003601.0

(51) Int. Cl. G01D 5/24; B62D 1/06

(52) U.S. Cl. CPC G01D 5/24; B62D 1/06

(57) ABSTRACT

A method for detecting a presence of a human hand in a gripping area of a steering wheel with the use of a capacitive sensor system is provided. The steering wheel includes a metal steering-wheel core connected to ground. The presence of the hand in a detection range of a sensor electrode arranged on the steering wheel and connected to sensor electronics brings about a change in a capacitive coupling (C_{Hand}) of the sensor electrode at a reference potential as compared with a reference state without the presence of the hand. Via a diagnostic measurement, a measure (ΔU_{Humid}) of environmental influences (C_{Humid}, R_{Humid}) on capacitive and ohmic couplings between the sensor electrode and the steering-wheel core attributable to water retention in the steering wheel is determined. The measure of the environmental influences is used for correcting the determination of the capacitive coupling of the sensor electrode at the reference potential.

### CROSS-REFERENCE TO RELATED APPLICATIONS

This application is a continuation of International Application No. PCT/EP2023/076497, published in German, with an international filing date of Sep. 26, 2023, which claims priority to DE 10 2022 003 601.0, filed Sep. 29, 2022, the disclosures of which are hereby incorporated in their entirety by reference herein.

### TECHNICAL FIELD

The present invention relates to a method for detecting a presence of a human hand in a gripping area of a steering wheel by means of a capacitive sensor system, wherein the presence of the hand in a detection range of a sensor structure including a sensor electrode(s) connected to an input/output of a sensor electronics system brings about a change in a capacitive coupling of the sensor electrode to a reference potential in comparison to a reference state without the presence of the hand in the gripping area, and a metal steering wheel core is connected to a ground potential.

### BACKGROUND

The sensor electrodes used here involve a one- or multi-layer structure of conductive sensor mats in the steering wheel rim. These capacitive sensor systems are referred to as hands-on detection (HOD) sensor systems. The presence of an operator's hand may be detected via a capacitive measurement. Use is made of the fact that a capacitive coupling exists between the hand and the sensor electrode, whose capacitance C_{Hand} is a function of the gripping state. The task of an associated sensor electronics system, or a measuring method used by such system, is to detect a change in the capacitance C_{Hand} caused by a change in the gripping state.

A difficulty is that the capacitance C_{Hand}, and particularly the changes thereof to be detected, are relatively much smaller in comparison to other internal capacitances of the steering wheel. For this reason, a so-called integration method is preferably used for this measurement. Pursuant to the integration method, in multiple consecutive cycles, small charge quantities are transferred from the sensor electrode, whose capacitance value is relatively small and variable, to an integration capacitor having a known, fixed capacitance value that is much greater. The voltage present at the integration capacitor after a predefined number of such integration cycles is measured using an A/D converter and processed to form a sensor amplitude. The sensor amplitude is a direct measure of the capacitance C_{Hand}. Other factors that may influence the measured capacitance must therefore be held constant to the greatest extent possible. For this purpose, in particular the steering wheel core is connected to a fixed potential.

Sensor systems for steering wheels of motor vehicles for hand detection, using capacitive sensor structures, are known from the prior art. For example, DE 203 09 603 U1 discloses a steering wheel having sensor electrodes, arranged in sectors, which allow the approach and/or distancing of a human hand to be detected and associated with a certain area of the steering wheel.

WO 2016/087279 A1 discloses a steering wheel for a motor vehicle, having a capacitive sensor system whose sensor structure may also be operated, at least temporarily, as a heating structure. The steering wheel has a metal steering wheel core that may be operated as an active shielding element and acted on by a defined electric potential to reduce an interfering capacitive coupling of the sensor structure to the steering wheel core.

Due to the capacitance C_{Core} between the steering wheel core and a sensor electrode, which is much greater in comparison to the capacitance C_{Hand} between a human hand and the sensor electrode, a change in potential of the steering wheel core has an interfering effect on the HOD measurement. The connection of the steering wheel core to a fixed potential, which is provided to avoid this problem, takes place in a sensor electronics system. This fixed potential connection, which generally occurs at a ground potential GND, typically has a capacitance of C_{GND}>100 nF.

The sensor electrodes and the steering wheel core are customarily connected via plug connectors to a wire harness that is led to the HOD electronics system and likewise connected thereto via plug connectors.

This situation as well as the relevant physical variables are schematically illustrated in FIG. 2, which illustrates a conventional HOD sensor system.

The substrates and filler materials that are used for installing the sensor electrodes and for forming the haptics of the steering wheel are generally materials that absorb water under environmental conditions with high humidity. The water that is incorporated into these materials has a relatively large influence on their electrical conductivities and dielectric constants. Therefore, the capacitive as well as ohmic coupling between the individual layers of the sensor electrodes and their coupling to the steering wheel core and/or to a steering wheel heating system are influenced by the water retention. The coupling is illustrated in FIG. 1, which illustrates a HOD sensor system in accordance with embodiments of the present invention, with only the capacitive and ohmic couplings (capacitance C_{Humid} and resistance R_{Humid}) between a sensor electrode and the steering wheel core being illustrated for reasons of clarity.

It has been found to be problematic that the influence of the water retention on the HOD measurement may be much greater than the influence by different gripping states. In addition, the influence of the gripping state itself is also changed in such a way that, when performing a simple value range analysis, a presumably different gripping state than the gripping state present may be erroneously detected.

Although environmental sensors, for example NTC sensors, are customarily installed in the steering wheel and evaluated, they are usually used only for protection, not for compensation. Because separate sensors are involved, the influence also does not correlate sufficiently with the HOD measurement to allow compensation of the HOD measured values in real time.

### SUMMARY

Embodiments of the present invention provide a method for detecting a presence of a human hand in a gripping area of a steering wheel. The method is for use with a capacitive sensor system in detecting the presence of the hand in the gripping area of the steering wheel. The capacitive sensor system includes a sensor electronics system and a sensor structure. The sensor structure includes at least one sensor electrode. The sensor electrode is connected to an input/output of the sensor electronics system. The steering wheel includes a metal steering wheel core which is connected to a ground potential (GND). The presence of the hand in a detection range of the sensor electrode brings about a change in a capacitive coupling C_{Hand} of the sensor electrode to a reference potential in comparison to a reference state without the presence of the hand in the gripping area.

The method incudes determining the capacitive coupling C_{Hand} of the sensor electrode to the reference potential. The method further includes performing at least one diagnostic measurement in which a measure ΔU_{Humid} of the environmental influences of the capacitive coupling C_{Humid} and the ohmic coupling R_{Humid} between the sensor electrode and the steering wheel core caused by water retention in the steering wheel is determined. The method further includes using the measure ΔU_{Humid} of the environmental influences (C_{Humid} and R_{Humid}) to correct the determination of the capacitive coupling C_{Hand} of the sensor electrode to the reference potential.

A method for detecting a presence of a human hand in a gripping area of a steering wheel in accordance with embodiments of the present invention has the advantage, over the above-described background art, of being a diagnostic method that correlates with the influence on the hands-on detection (HOD) measurement, and thus allows a correction of the HOD measurement to compensate for the environmental influences in real time to avoid the described errors.

This is achieved according to the present invention in that, by means of at least one diagnostic measurement, a measure ΔU_{Humid} of the environmental influences C_{Humid} and R_{Humid}, brought about by water retention in the steering wheel, on the capacitive coupling and ohmic coupling between the sensor electrode and the steering wheel core is determined and used to correct the determination of the capacitive coupling of the sensor electrode to the reference potential.

In one preferred embodiment of the method, the diagnostic measurement includes determining the discharge of a capacitor having the capacitance C across a resistor R_{Humid} during a fixed waiting period Δt, where the measure ΔU_{Humid} is the difference between a starting voltage U₀ and a voltage U_{Humid} after the waiting period Δt.

The diagnostic measurement is advantageously cyclically repeated at a predefined sampling rate.

A capacitive sensor system for detecting a presence of a human hand in a gripping area of the steering wheel is also provided. The steering wheel includes a metal steering wheel core connected to a ground potential. The capacitive sensor system includes a sensor electronics system and a sensor structure. The sensor structure includes a sensor electrode arranged on the steering wheel and connected to an input/output of the sensor electronics system. The sensor electronics system is configured to determine a capacitive coupling C_{Hand} of the sensor electrode to a reference potential. A presence of a human hand in a detection range of the sensor electrode brings about a change in the capacitive coupling C_{Hand} of the sensor electrode to the reference potential in comparison to a reference state without the presence of the human hand in the detection range of the sensor electrode. The sensor electronics system is further configured to perform a diagnostic measurement to determine a ΔU_{Humid} of environmental influences of a capacitive coupling C_{Humid} and an ohmic coupling R_{Humid} between the sensor electrode and the steering wheel core caused by water retention in the steering wheel, and to correct the determined capacitive coupling C_{Hand} of the sensor electrode to the reference potential according to the determined ΔU_{Humid}.

Further advantageous embodiments of the method according to the present invention result from the following description of one possible design of the present invention.

### BRIEF DESCRIPTION OF THE DRAWINGS

The present invention is explained below with reference to the appended drawings.

In the drawings:

FIG. 1 shows a schematic illustration of an embodiment of a hands-on detection (HOD) sensor system for carrying out a method according to the present invention, and relevant physical variables; and

FIG. 2 shows a schematic illustration of a conventional HOD sensor system, and relevant physical variables.

### DETAILED DESCRIPTION

Detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

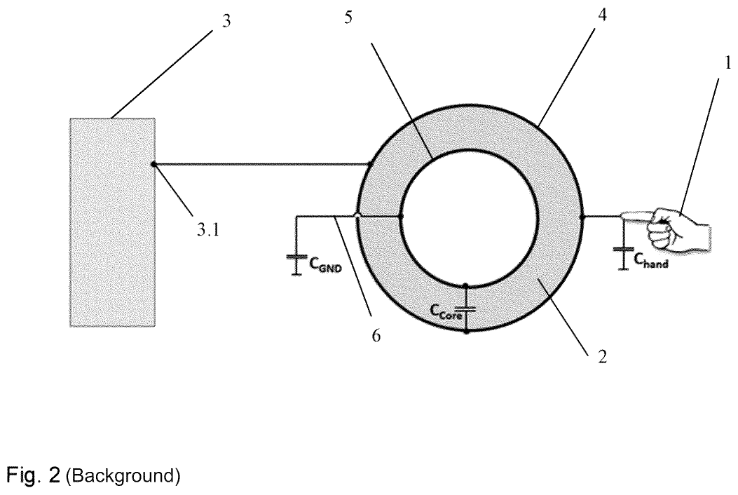

Referring initially to FIG. 2, a conventional hands-on detection (HOD) sensor system for detecting a presence of a human hand 1 in a gripping area of a steering wheel 2 is shown. The conventional HOD sensor system includes a sensor electronics system 3 and a sensor structure. The sensor structure includes at least one sensor electrode 4. Sensor electrode 4 is arranged on steering wheel 2 and is connected to an input/output 3.1 of sensor electronics system 3.

Steering wheel 2 includes a metal steering wheel core 5. Steering wheel core 5 is connected via one or more connection lines 6 to a fixed potential, which is generally a ground potential GND. This connection has a capacitance of typically C_{GND}>100 nF. Both single and multiple contacting of steering wheel core 5 are known; multiple contacting increases the robustness of the connection. A capacitance C_{Core} is between sensor electrode 4 and steering wheel core 5.

The presence of hand 1 in a detection range of sensor electrode 4 brings about a change in a capacitive coupling C_{Hand} of the sensor electrode to the hand. The change in the capacitive coupling C_{Hand} between sensor electrode 4 and hand 1 is detectable via input/output 3.1 of sensor electronics system 3. The capacitance C_{Core} between sensor electrode 4 and steering wheel core 5 is much greater in comparison than the capacitive coupling C_{Hand} between sensor electrode 4 and hand 1.

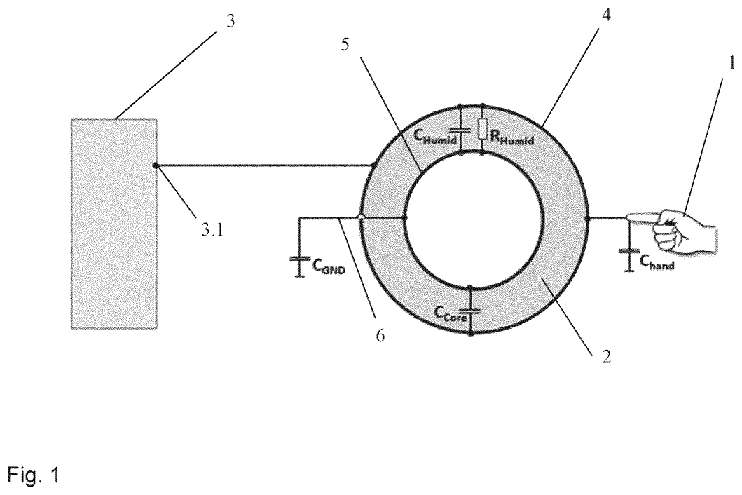

Referring now to FIG. 1, with continual reference to FIG. 2, an embodiment of a HOD sensor system for carrying out a method variant according to the present invention is shown. The basic design of the HOD sensor system is identical to the above description of the conventional HOD sensor system shown in FIG. 2. In this regard, the HOD sensor system according to the present invention also includes a sensor electronics system 3 and a sensor structure, the sensor structure including at least one sensor electrode 4, and sensor electrode 4 is arranged on steering wheel 2 and is connected to an input/output 3.1 of sensor electronics system 3. Likewise, the basic method steps carried out by the HOD sensor system according to the present invention for detecting the presence of a hand 1 in a gripping area of a steering wheel 2 are the same as set forth in the above description concerning the conventional HOD sensor system shown in FIG. 2. Lastly, steering wheel 2 includes a metal steering wheel core 5, per the above description concerning the conventional HOD sensor system shown in FIG. 2.

In addition, in FIG. 1 the capacitive coupling C_{Humid} and the ohmic coupling R_{Humid} between sensor electrode 4 and steering wheel core 5 are illustrated. As indicated above, the capacitive coupling C_{Humid} and the ohmic coupling R_{Humid} between sensor electrode 4 and steering wheel core 5 represent the environmental influences caused by water retention in steering wheel 2. The total capacitance C of the capacitive coupling between sensor electrode 4 and steering wheel core 5 is therefore C=C_{Core}+C_{Humid}.

To carry out the method according to the present invention, sensor electrode 4 is initially charged with a defined voltage U_{HOD}=U₀ via input/output 3.1 of sensor electronics system 3. This connection is subsequently separated, for example by switching input/output 3.1 of sensor electronics system 3 from “output” to “input.” The charge that is now stored on sensor electrode 4 can then flow off across ohmic coupling R_{Humid}. After a constant waiting period Δt, the voltage, which has then dropped to the value U_{Humid}, is measured via input/output 3.1 of sensor electronics system 3.

The discharge of a capacitor having the capacitance C across a resistor R_{Humid} takes place according to the equation: U_{Humid}=Uₒexp [−Δt/(R_{Humid}*C)].

In dry surroundings the resistance R_{Humid} is practically infinite, so that the determined voltage U_{Humid}˜U₀.

The change that is measured under actual conditions, i.e., with incorporated water in the materials used, ΔU_{Humid}=Uₒ−U_{Humid}, is thus a measure of the environmental influences C_{Humid} and R_{Humid} but is largely independent of the capacitance C_{Hand}.

Since according to the present invention, the same sensor electronics system and sensor structure are used as for the HOD measurement itself, ΔU_{Humid} correlates with the HOD measurement U_{HOD}, and due to the independence from C_{Hand} may be used as a correction factor.

When this diagnosis is carried out cyclically at a sufficient sampling rate, real-time compensation of the environmental influences is possible during runtime.

While exemplary embodiments are described above, it is not intended that these embodiments describe all possible forms of the present invention. Rather, the words used in the specification are words of description rather than limitation, and it is understood that various changes may be made without departing from the spirit and scope of the present invention. Additionally, the features of various implementing embodiments may be combined to form further embodiments of the present invention.

What is claimed is:

1. A method for detecting a presence of a human hand in a gripping area of a steering wheel by means of capacitive sensor system, the capacitive sensor system including a sensor electronics system and a sensor structure, the sensor structure including a sensor electrode arranged on the steering wheel and connected to an input/output of the sensor electronics system, wherein the steering wheel includes a metal steering wheel core connected to a ground potential, the method comprising:
determining, by the sensor electronics system, a capacitive coupling C_{Hand} of the sensor electrode to a reference potential, wherein a presence of the human hand in a detection range of the sensor electrode brings about a change in the capacitive coupling of the sensor electrode to the reference potential in comparison to a reference state without the presence of the human hand in the detection range of the sensor electrode;
performing, by the sensor electronics system, a diagnostic measurement to determine a ΔU_{Humid} of environmental influences of a capacitive coupling C_{Humid} and an ohmic coupling R_{Humid} between the sensor electrode and the metal steering wheel core caused by water retention in the steering wheel; and
correcting the determined capacitive coupling C_{Hand} of the sensor electrode to the reference potential according to the determined ΔU_{Humid}.

2. The method according to claim 1, wherein performing the diagnostic measurement includes determining a discharge of a capacitor having a capacitance C across a resistor R having the ohmic coupling R_{Humid} during a waiting period Δt, wherein the determined ΔU_{Humid} is a difference between a starting voltage U₀ and a voltage U_{Humid} after the waiting period Δt.

3. The method according to claim 2, wherein performing the diagnostic measurement is cyclically repeated at a predefined sampling rate.

4. The method according to claim 1, wherein performing the diagnostic measurement is cyclically repeated at a predefined sampling rate.

5. A capacitive sensor system for detecting a presence of a human hand in a gripping area of a steering wheel, wherein the steering wheel includes a metal steering wheel core connected to a ground potential, the capacitive sensor system comprising:
a sensor electronics system; and
a sensor structure including a sensor electrode arranged on the steering wheel and connected to an input/output of the sensor electronics system;
wherein the sensor electronics system is configured to determine a capacitive coupling C_{Hand} of the sensor electrode to a reference potential, wherein a presence of the human hand in a detection range of the sensor electrode brings about a change in the capacitive coupling C_{Hand} of the sensor electrode to the reference potential in comparison to a reference state without the presence of the human hand in the detection range of the sensor electrode;
the sensor electronics system is further configured to perform a diagnostic measurement to determine a ΔU_{Humid} of environmental influences of a capacitive coupling C_{Humid} and an ohmic coupling RΠumid between the sensor electrode and the metal steering wheel core caused by water retention in the steering wheel, and to correct the determined capacitive coupling C_{Hand} of the sensor electrode to the reference potential according to the determined ΔU_{Humid}.

6. The capacitive sensor system according to claim 5, wherein in performing the diagnostic measurement the sensor electronics system is further configured to determine a discharge of a capacitor having a capacitance C across a resistor R having the ohmic coupling R_{Humid} during a waiting period Δt, wherein the determined ΔU_{Humid} is a difference between a starting voltage U₀ and a voltage U_{Humid} after the waiting period Δt.

7. The capacitive sensor system according to claim 6, wherein the sensor electronics system is further configured to perform the diagnostic measurement repeatedly at a predefined sampling rate.

8. The capacitive sensor system according to claim 5, wherein the sensor electronics system is further configured to perform the diagnostic measurement repeatedly at a predefined sampling rate.
